(19) United States
(12) Patent Application Publication
(10) Pub. No.: US 2010/0310769 A1
(43) Pub. Date: Dec. 9, 2010

(54) Continuous Feed Chemical Vapor Deposition System

(75) Inventors: Eric Armour, Pennington, NJ (US); William E. Quinn, Whitehouse Station, NJ (US); Piero Sferlazzo, Marblehead, MA (US)

Correspondence Address: RAUSCHENBACH PATENT LAW GROUP, LLP, P.O. BOX 387, BEDFORD, MA, 01730, US

(73) Assignee: Veeco Compound Semiconductor, Inc., Somerset, NJ (US)

(21) Appl. No.: 12/479,834

(22) Filed: Jun. 7, 2009

(51) Int. Cl. C23C 16/44

(52) U.S. Cl. 427/255.7; 118/719

(57) ABSTRACT

A continuous feed CVD system includes a wafer transport mechanism that transport a wafer through a deposition chamber during CVD processing. The deposition chamber defines a passage for the wafer to pass through while being transported by the wafer transport mechanism. The deposition chamber includes a plurality of process chambers that are isolated by barriers which maintain separate process chemistry in each of the plurality of process chambers. Each of the plurality of process chambers includes a gas input port and a gas exhaust port, and a plurality of CVD gas sources. At least two of the plurality of CVD gas sources are coupled to the gas input port of each of the plurality of process chambers.

The section headings used herein are for organizational purposes only and should not to be construed as limiting the subject matter described in the present application in any way.

### INTRODUCTION

Chemical vapor deposition (CVD) involves directing one or more gases containing chemical species onto a surface of a substrate so that the reactive species react and form a film on the surface of the substrate. For example, CVD can be used to grow compound semiconductor material on a crystalline semiconductor wafer. Compound semiconductors, such as III-V semiconductors, are commonly formed by growing various layers of semiconductor materials on a wafer using a source of a Group III metal and a source of a Group V element. In one CVD process, sometimes referred to as a chloride process, the Group III metal is provided as a volatile halide of the metal, which is most commonly a chloride, such as GaCl₂, and the Group V element is provided as a hydride of the Group V element.

Another type of CVD is metal organic chemical vapor deposition (MOCVD). MOCVD uses chemical species that include one or more metal organic compounds, such as alkyls of the Group III metals, such as gallium, indium, and aluminum. MOCVD also uses chemical species that include hydrides of one or more of the Group V elements, such as NH₃, AsH₃, PH₃ and hydrides of antimony. In these processes, the gases are reacted with one another at the surface of a wafer, such as a wafer of sapphire, Si, GaAs, InP, InAs or GaP, to form a III-V compound of the general formula In_{X}Ga_{Y}Al_{Z}N_{A}As_{B}P_{C}Sb_{D}, where X+Y+Z equals approximately one, and A+B+C+D equals approximately one, and each of X, Y, Z, A, B, and C can be between zero and one. In some instances, bismuth may be used in place of some or all of the other Group III metals.

Another type of CVD is known as Halide Vapor Phase Epitaxy (HVPE). In one HVPE process, Group III nitrides (e.g., GaN, AlN) are formed by reacting hot gaseous metal chlorides (e.g., GaCl or AlCl) with ammonia gas (NH₃). The metal chlorides are generated by passing hot HCl gas over the hot Group III metals. All reactions are done in a temperature controlled quartz furnace. One feature of HVPE is that it can have a very high growth rate, up to 100 μm per hour for some state-of-the-art processes. Another feature of HVPE is that it can be used to deposit relatively high quality films because films are grown in a carbon free environment and because the hot HCl gas provides a self-cleaning effect.

### BRIEF DESCRIPTION OF THE DRAWINGS

The present teaching, in accordance with preferred and exemplary embodiments, together with further advantages thereof, is more particularly described in the following detailed description, taken in conjunction with the accompanying drawings. The skilled person in the art will understand that the drawings, described below, are for illustration purposes only. The drawings are not necessarily to scale, emphasis instead generally being placed upon illustrating principles of the teaching. The drawings are not intended to limit the scope of the Applicant's teaching in any way.

FIG. 1A illustrates a top-view of one embodiment of a continuous feed CVD system for CVD deposition on wafers according to the present teaching.

FIG. 1B illustrates a side-view of one embodiment of a continuous feed CVD system for CVD deposition on wafers according to the present teaching.

FIG. 2A illustrates a bottom-view of a plurality of horizontal gas intake ports in one of the plurality of process chambers in the deposition chamber.

FIG. 2B illustrates a side-view of a portion of a process chamber including a single horizontal gas intake port and a single gas exhaust port in a process chamber of a continuous feed CVD system according to the present teaching.

FIG. 2C illustrates a graph of film thickness as a function of the width of the wafer which illustrates how a uniform film thickness can be achieved across the entire width of the wafer.

FIG. 3A illustrates a bottom-view and a side-view of a single vertical gas source for the continuous feed CVD system according to the present teaching.

FIG. 3B illustrates a side-view of a plurality of vertical gas sources for the continuous feed CVD system according to the present teaching that is positioned along the wafer transport mechanism so that each of the plurality of vertical gas sources distribute process gasses over the surface of the wafer.

FIG. 4A illustrates a top-view and a side-view of a single vertical exhaust port for the continuous feed CVD system according to the present teaching.

FIG. 4B illustrates the positioning of a single vertical exhaust port in a process chamber opposite to a plurality of vertical gas sources.

### DESCRIPTION OF VARIOUS EMBODIMENTS

Reference in the specification to “one embodiment” or “an embodiment” means that a particular feature, structure, or characteristic described in connection with the embodiment is included in at least one embodiment of the teaching. The appearances of the phrase “in one embodiment” in various places in the specification are not necessarily all referring to the same embodiment.

It should be understood that the individual steps of the methods of the present teachings may be performed in any order and/or simultaneously as long as the teaching remains operable. Furthermore, it should be understood that the apparatus and methods of the present teachings can include any number or all of the described embodiments as long as the teaching remains operable.

The present teaching will now be described in more detail with reference to exemplary embodiments thereof as shown in the accompanying drawings. While the present teaching is described in conjunction with various embodiments and examples, it is not intended that the present teaching be limited to such embodiments. On the contrary, the present teaching encompasses various alternatives, modifications and equivalents, as will be appreciated by those of skill in the art. Those of ordinary skill in the art having access to the teaching herein will recognize additional implementations, modifications, and embodiments, as well as other fields of use, which are within the scope of the present disclosure as described herein.

The present teaching relates to methods and apparatus for reactive gas phase processing, such as CVD, MOCVD, and HVPE. In reactive gas phase processing of semiconductors materials, semiconductor wafers are mounted in a wafer carrier inside a reaction chamber. A gas distribution injector or injector head is mounted facing towards the wafer carrier. The injector or injector head typically includes a plurality of gas inlets that receive a combination of gases. The injector or injector head provides the combination of gasses to the reaction chamber for chemical vapor deposition. Many gas distribution injectors have showerhead devices spaced in a pattern on the head. The gas distribution injectors direct the precursor gases at the wafer carrier in such a way that the precursor gases react as close to the wafers as possible, thus maximizing reaction processes and epitaxial growth at the wafer surface.

Some gas distribution injectors provide a shroud that assists in providing a laminar gas flow during the chemical vapor deposition process. Also, one or more carrier gases can be used to assist in providing a laminar gas flow during the chemical vapor deposition process. The carrier gas typically does not react with any of the process gases and does not otherwise affect the chemical vapor deposition process. A gas distribution injector typically directs the precursor gases from gas inlets of the injector to certain targeted regions of the reaction chamber where wafers are processed.

For example, in MOCVD processes, the injector introduces combinations of precursor gases including metal organics and hydrides, such as ammonia or arsine into a reaction chamber through the injector. A carrier gases, such as hydrogen, nitrogen, or inert gases, such as argon or helium, is often introduced into the reactor through the injector to aid in maintaining laminar flow at the wafer carrier. The precursor gases mix in the reaction chamber and react to form a film on a wafer. Many compound semiconductors, such as GaAs, GaN, GaAlAs, InGaAsSb, InP, ZnSe, ZnTe, HgCdTe, InAsSbP, InGaN, AlGaN, SiGe, SiC, ZnO and InGaAlP, have been grown by MOCVD.

In both MOCVD and HVPE processes, the wafer is maintained at an elevated temperature within a reaction chamber. The process gases are typically maintained at a relatively low temperature of about 50-60° C. or below, when they are introduced into the reaction chamber. As the gases reach the hot wafer, their temperature, and hence their available energy for reaction, increases.

The most common type of CVD reactor is a rotating disc reactor. Such a reactor typically uses a disc-like wafer carrier. The wafer carrier has pockets or other features arranged to hold one or more wafers to be treated. The carrier, with the wafers positioned thereon, is placed into a reaction chamber and held with the wafer-bearing surface of the carrier facing in an upstream direction. The carrier is rotated, typically at rotational velocities of several hundred revolutions per minute, about an axis extending in the upstream to downstream direction. The rotation of the wafer carrier improves uniformity of the deposited semiconductor material. The wafer carrier is maintained at a desired elevated temperature, which can be in the range of about 350° C. to about 1,600° C. during this process.

While the carrier is rotated about the axis, the reaction gases are introduced into the chamber from a flow inlet element above the carrier. The flowing gases pass downwardly toward the carrier and wafers, preferably in a laminar plug flow. As the gases approach the rotating carrier, viscous drag impels them into rotation around the axis so that in a boundary region near the surface of the carrier, the gases flow around the axis and outwardly toward the periphery of the carrier. As the gases flow over the outer edge of the carrier, they flow downwardly toward exhaust ports positioned below the carrier. Most commonly, MOCVD processes are performed with a succession of different gas compositions and, in some cases, different wafer temperatures, to deposit a plurality of layers of semiconductor having differing compositions as required to form a desired semiconductor device.

Known apparatus and methods for CVD, such as MOCVD and HVPE, are not suitable for linear processing systems, such as continuous feed deposition systems that are commonly used for depositing materials on a wafer. The apparatus and methods of the present teaching can perform any type of CVD, such as MOCVD and HVPE, on wafers positioned in a linear transport system. One particular application for such apparatus and methods is the fabrication of solar cells. Another particular application for such apparatus and methods is the fabrication of superconducting materials.

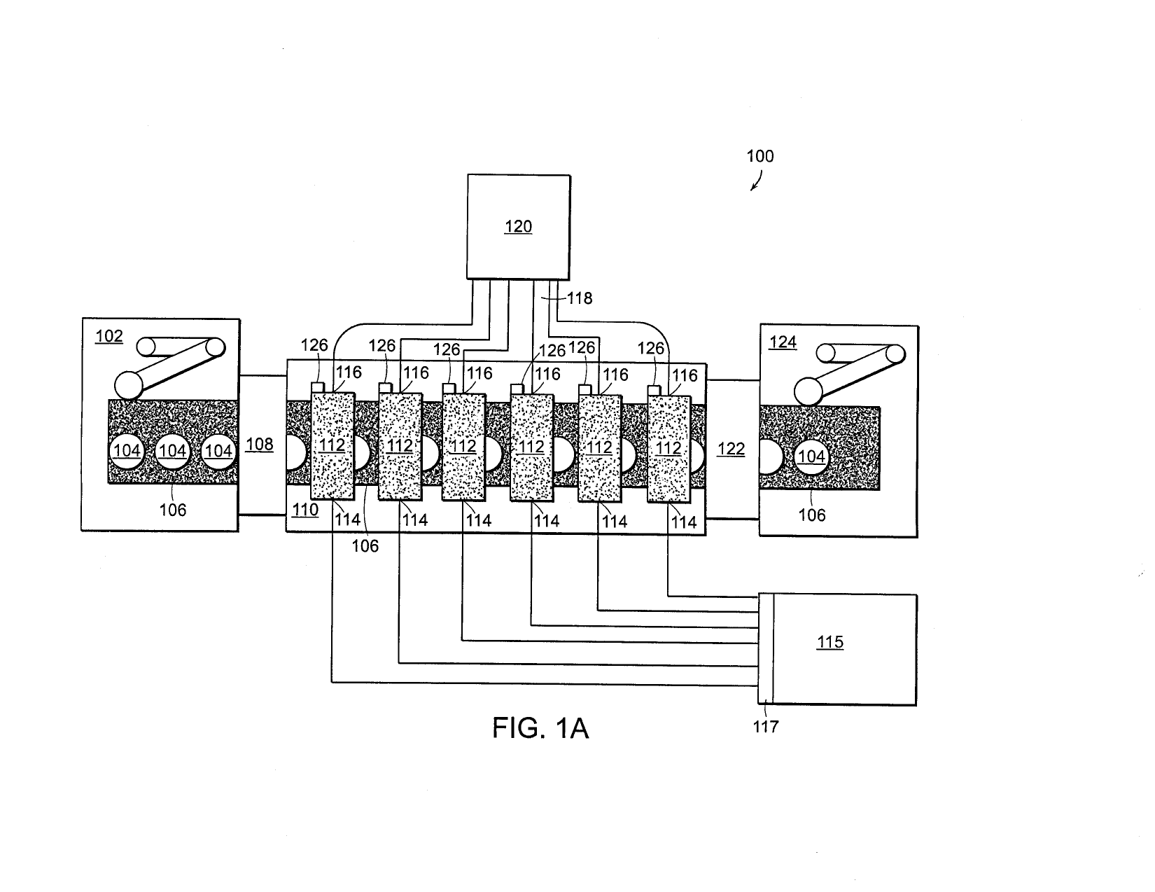

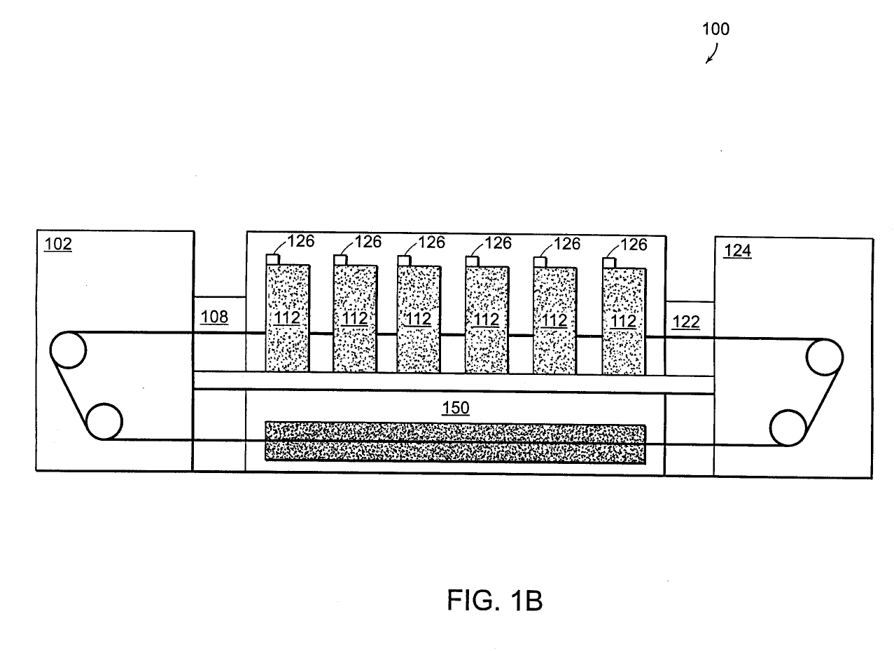

FIG. 1A illustrates a top-view of one embodiment of a continuous feed CVD system 100 for CVD deposition on wafers according to the present teaching. The continuous feed CVD system 100 is designed to process wafers, such as semiconductor wafers that are commonly used in the art. For example, the continuous feed CVD system 100 can be used to process semiconductor wafers to fabricate solar cell devices.

More specifically, the continuous feed CVD system 100 includes a wafer loading station 102 that load wafers 104 onto a continuous feed wafer transport mechanism 106. The wafer loading station 102 is typically at atmospheric pressure. An input load lock or isolation chamber 108 is coupled to the wafer loading station 102 with a gate valve and interfaces the wafer loading station 102 to one end of a deposition chamber 110 that includes a plurality of process chambers 112. The isolation chamber 108 can be at an intermediate pressure between atmospheric pressure and the pressure in the plurality of process chambers 112. In many embodiments, the isolation chamber 108 is coupled to a source of purge gas and a vacuum pump to perform a pump/purge cycle.

The wafer transport mechanism 106 transports the wafer 104 through the plurality of process chambers 112. The wafer transport mechanism 106 can include a plurality of wafer carrier that supports the wafers 104. Alternatively, the wafer transport mechanism 106 includes air bearings that inject gas under the wafers 104 so that the wafers 104 are supported over wafer transport mechanism 106. In some systems, the air bearings move the wafers over wafer transport mechanism 106 in a controlled manner. Some types of air bearing are designed so that the wafers 104 move over wafer transport mechanism 106 in a spiral motion.

In many embodiments, the wafer transport mechanism 106 transports the wafers 104 through the deposition chamber 106 in one direction. However, in other embodiments, the wafer transport mechanism 106 transports the wafers 104 through the deposition chamber 106 in a first direction and then back through the deposition chamber 106 in a second direction that is opposite to the first direction. Also, in various processes, the wafer transport mechanism 106 transports the wafers 104 in a continuous mode or in a stepwise mode. In the continuous mode, the wafer transport mechanism 106 transports the wafers 104 at a constant transport rate. In the stepwise mode, the wafer transport mechanism 106 transports the wafers 104 through the deposition chamber 106 in a plurality of discrete steps where, in each step, the wafers 104 are stationary for a predetermined process time so that they are exposed to a CVD process in the plurality of process chambers 112.

The deposition chamber 110 defines a passage for the wafers 104 to pass through so that the wafers 104 transports through the plurality of process chambers 112. Each of the plurality of process chambers 112 is isolated from each of the other process chambers 112 by barriers which maintain separate process chemistry. One skilled in the art will appreciate that many different types of barriers can be used to maintain separate process chemistries in each of the plurality of process chambers 112.

For example, the barriers that maintain separate process chemistries in each of the plurality of process chambers 112 can be gas curtains that inject an inert gas between adjacent process chambers 112 to prevent gasses in adjacent process chambers 112 from mixing, thereby maintaining separate process chemistries in each of the plurality of process chambers 112. In addition, the barriers can be vacuum regions that are positioned between adjacent process chambers 112 that remove gasses between adjacent process chambers 112 so that separate process chemistries are maintained in each of the plurality of process chambers 112.

Each of the plurality of process chambers 112 includes at least one gas input port 114 that is coupled to at least one CVD process gas source 115 so that the at least one gas input port 114 injects at least one process gas into the process chamber 108. The process gasses can be located proximate to the CVD system 100 or can be located in a remote location. In many embodiments, a plurality of CVD gas sources, such as MOCVD gas sources, is available to be connected to the gas input ports 114 of each of the plurality of process chambers 112 through a gas distribution manifold 117. One feature of the present teaching is that the deposition system 100 can be easily configured to change the material structure being deposited by configuring the gas distribution manifold 117. For example, the gas distribution manifold 117 can be configured manually at the manifold 117 or can be configured remotely by activating electrically operated valves and solenoids. Such an apparatus is well suited for research environments because it can be easily reconfigured to change the deposited material structure.

The gas input ports 114 can include a gas distribution nozzle that substantially prevents CVD gases from reacting until the at least one CVD gas reaches the wafers 104. Such a gas distribution nozzle prevents reaction by-products from embedding into the material deposited on the surface of the wafers 104. In addition, each of the plurality of process chambers 112 includes at least one gas exhaust port 116 that provides an exit for process gases and reaction by-product gasses. The at least one exhaust port 116 for each of the plurality of process chambers 112 is coupled to an exhaust manifold 118. A vacuum pump 120 is coupled to the exhaust manifold 118. The vacuum pump 120 evacuates the exhaust manifold, thereby creating a pressure differential which removes the process gases and reaction by-product gasses from the plurality of process chambers 112.

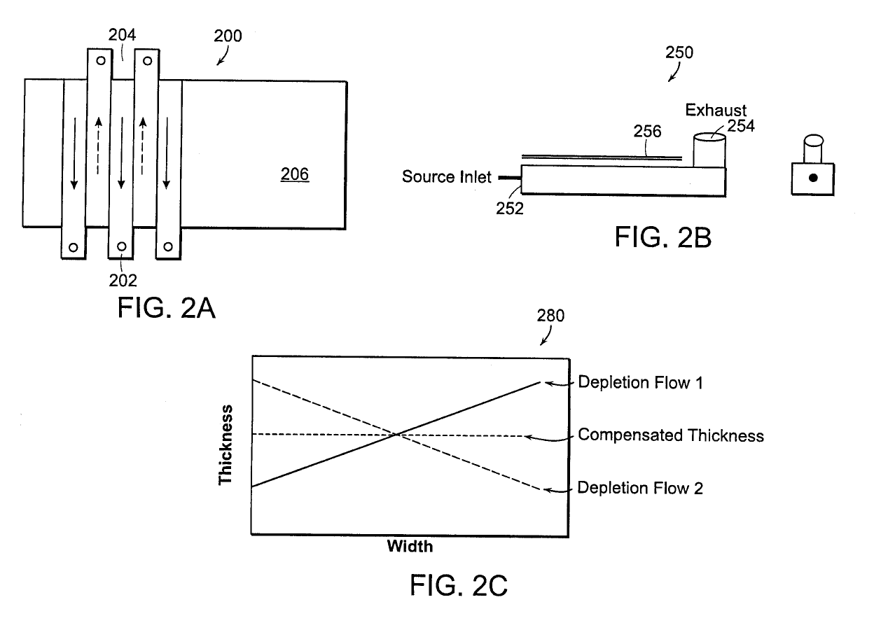

The gas input ports 114 and the gas exhaust ports 116 can be configured in various ways depending upon the deposition chamber design and the desired processing conditions. In many embodiments, the gas input ports 114 and the gas exhaust ports 116 are configured to substantially prevent reactions of process gases from occurring away from the wafers 104, thereby preventing contamination of the deposited film. FIGS. 2A, 2B, 2C, 3A, 3B, 4A and 4B show various configurations of gas input 114 and gas exhaust ports 116.

In many embodiments, the gas input ports 114 are positioned at a first location and the gas exhaust ports 116 are positioned at a second location. For example, in one specific embodiment, the gas input ports 114 are positioned in an upper surface of the process chambers 112 and the gas exhaust ports 116 are positioned at one side of the process chambers 112. In another specific embodiment, the gas input ports 114 are positioned at one side of the process chambers 112 and the corresponding exhaust ports 116 are positioned at the other side of the process chambers 112 so that the CVD process gasses flow across the process chambers 112.

In another embodiment, at least two gas input ports 114 are positioned at different locations in various configurations. For example, in one specific embodiment, one gas input port 114 is positioned to flow gas down onto the wafers 104, while another gas input port 114 is positioned to flow gas across the wafers 104. Such a configuration could be used to flow arsine gas down onto the wafers 104 while simultaneously flowing TMG gas across the wafers 104 to create a uniform mixture of gases for MOVCD.

In another embodiment, at least two exhaust ports 116 are positioned at different locations in at least some of the plurality of deposition chambers 112. For example, in one specific embodiment, exhaust ports 116 are positioned at both sides of at least some of the plurality of process chambers 112 so that pumping of the process gasses occurs across the entire surface of the wafers 104.

In another embodiment, at least some process chambers 112 are configured to have at least one gas input port 114 on one side of the wafers 104 and at least one exhaust port 116 on the other side of the wafers 104. Highly uniform deposition thicknesses can be achieved across the wafers 104 by alternating the side of the gas input ports 114 in subsequent process chambers 112. For example, a first process chamber 112 can be configured to have a gas input port 114 on a first side of the wafers 104 and an exhaust port 116 on a second side of the wafers 104; and a second subsequent process chamber 112 can be configured to have a gas input port 114 on the second side of the wafers 104 and an exhaust port 116 on the first side of the wafers 104. This configuration can be repeated with some or all of the subsequent process chambers 112. See, for example, the graph 280 shown in FIG. 2C which illustrates how a uniform deposition thickness can be obtained when process gasses are injected at opposite sides of the wafers 104 in alternating processing chambers 112.

In another embodiment, at least some process chambers 112 are configured to have at least one gas input port 114 below the wafers 104 and at least one exhaust port 116 on one or both sides of the wafers 104. In yet another embodiment, at least some process chambers 112 are configured to have at least one gas input port 114 above the wafers 104 and at least one exhaust port 116 on one or both sides of the wafers 104.

The wafers 104 are heated for many CVD processes. There are numerous types of heaters that can be used to heat the wafers 104 to the desired process temperature while the wafers 104 are being transported through the plurality of process chambers 112. In one embodiment, a radiant heater is positioned proximate to the wafers 104 in order to heat the wafers 104 to a desired process temperature. In another embodiment, a heating element, such as a graphite heater, is positioned in thermal contact with the wafers 104 in order to heat the wafers 104 to a desired process temperature. In another embodiment, RF induction coils are positioned proximate to the wafers 104 so that energy from the RF induction coils heats the wafers 104. In yet another embodiment, the wafers 104 itself is used as a resistive heater. In this embodiment, the wafers 104 are constructed of a material and with a thickness that results in a resistivity which is suitable for resistive heating. A power supply is electrically connected to the wafers 104. The current generated by the power supply is regulated so that the wafers 104 are heated to the desired processing temperature. One skilled in the art will appreciate that other types of heaters can be used to heat the wafers 104. In addition, one skilled in the art will appreciate that more than one type of heater can be used to heat the wafers 104.

The processed wafers 104 pass through the other end of the deposition chamber 110 and into an output load lock or isolation chamber 122. A wafer unloading station 124 is coupled to the output load lock or isolation chamber 122. The wafer unloading station 124 unloads wafers 104 from the continuous feed wafer transport mechanism 106. The wafer unloading station 124 is typically at atmospheric pressure. The isolation chamber 122 can be at an intermediate pressure between atmospheric pressure and the pressure in the plurality of process chambers 112. In many embodiments, the isolation chamber 122 is coupled to a source of purge gas and a vacuum pump to perform a pump/purge cycle.

FIG. 1B illustrates a side-view of one embodiment of the continuous feed CVD system 100 for CVD deposition on wafers according to the present teaching. Referring to both FIGS. 1A and 1B, the side-view shows the wafer loading station 102 that load the wafers 104 onto the continuous feed wafer transport system 106, the input isolation chamber 108 that interfaces the wafer loading station 102 to the deposition chamber 110, and the output isolation chamber 122 that interfaces the other end of the deposition chamber 110 to the wafer unloading station 120 that were described in connection with FIG. 1A.

In addition, the side-view of the continuous feed CVD system 100 for CVD deposition shows a side-view of the continuous feed wafer transport mechanism 106 as it transports through a cleaning zone 150 that is positioned under the plurality of process chambers 112. The wafer transport mechanism 106 can be cleaned after wafers 104 are processed in the plurality of processing chambers 112. For example, the wafers 104 can be cleaned with a plasma cleaning or a thermal cleaning process.

One feature of the deposition system of the present teaching is that the material structure of the deposited film is defined by the geometry of the deposition chamber 110 because each of the plurality of process chambers 112 defines a layer in the material structure. In other words, the deposition process is spatially distributed in the deposition chamber 110. Thus, the geometry of the plurality of process chambers 112 in the deposition chamber 110 determines the material structure to a large extent. The process parameters, such as transport rate, gas flow rate, exhaust conductance, wafer temperature, and pressure in the plurality of process chambers 112 also determine characteristics of the material structure, such as the film quality and the film thickness. Such a deposition apparatus is very versatile and is suitable for mass production with high throughput. In addition, such a deposition apparatus is suitable for research applications because it can be easily reconfigured to change the deposited material structure.

Another feature of the deposition system of the present teaching is that the dimensions of the process chambers 112 and the transport rate of the wafers 104 define the CVD reaction time that the wafers 104 are exposed the process gases. Such a configuration does not rely on the accuracy of gas valves and, thus can result in a more accurate and repeatable CVD reaction time compared with known CVD processes. Another feature of the deposition system of the present teaching is that the system is highly repeatable because the wafers 104 are exposed to substantially the same process conditions.

Yet another feature of the deposition system of the present teaching is that the system can be easily configured to perform in-situ characterization of the films deposited on the wafers 104 in the deposition chamber 110. Thus, the continuous feed CVD system 100 can include in-situ measurement devices 126 positioned anywhere along the deposition chamber 110. For example, in-situ measurement devices 126 can be positioned in the CVD process chambers 112. One skilled in the art will appreciate that numerous types of in-situ measurement devices can be used to characterize the deposited films in the process chambers 112 or between process chambers 112.

For example, at least one of the in-situ measurement devices 126 can be a pyrometer that measures temperature during deposition. Pyrometers can provide a feedback signal that controls the output power of one or more heaters that control the temperature of the wafers 104. In various embodiments, one or more pyrometers can be used to control a single heater that controls the temperature of the deposition chamber 110 or can be used to control heaters that heat one or more individual CVD process chambers 112.

At least one of the in-situ measurement devices 126 can also be a reflectometer that measures thickness and/or growth rate of the deposited films. The reflectometer can provide a feedback signal that controls various deposition parameters, such as the transport rate of the wafer transport mechanism 106, process gas flow rate, and pressure in the CVD process chambers 112.

In one embodiment, the deposition chamber 106 has a means for configuring the physical dimensions of at least some of the plurality of process chambers 112 for a particular CVD process. For example, at least some of the plurality of process chambers 112 can be constructed so that they have adjustable dimensions. In addition, at least some of the plurality of process chambers 112 can be configured to be removable so that they are easily interchanged with other process chambers 112 having different dimensions. In such an apparatus, the operator can insert process chambers 112 into the deposition chamber 110 that corresponds to the desired material structure.

FIGS. 2A-2C illustrate various aspects of horizontal process gas injection in a process chamber 200 for a continuous feed CVD system according to the present teaching. FIG. 2A illustrates a bottom-view of a plurality of horizontal gas intake ports 202 in one of the plurality of process chambers 204 in the deposition chamber. The bottom-view shows the wafer transport mechanism 206 transporting over the plurality of gas intake ports 202 so that gasses injected from the plurality of gas intake ports 202 react on the surface of the wafers 206.

FIG. 2B illustrates a side-view of a portion of a process chamber 250 including a single horizontal gas intake port 252 and a single gas exhaust port 254 in a process chamber of a continuous feed CVD system according to the present teaching. The side-view 250 shows the wafer transport mechanism 256 transporting over the gas intake port 252.

FIG. 2C illustrates a graph 280 of film thickness as a function of the width of the wafer transport mechanism 256 (FIG. 2B). The graph 280 illustrates one method of achieving a uniform film thickness across the entire width of the wafers 256. The graph 280 illustrates that when process gasses are injected at opposite sides of the wafers in alternating process chambers, a highly uniform thickness can be achieved.

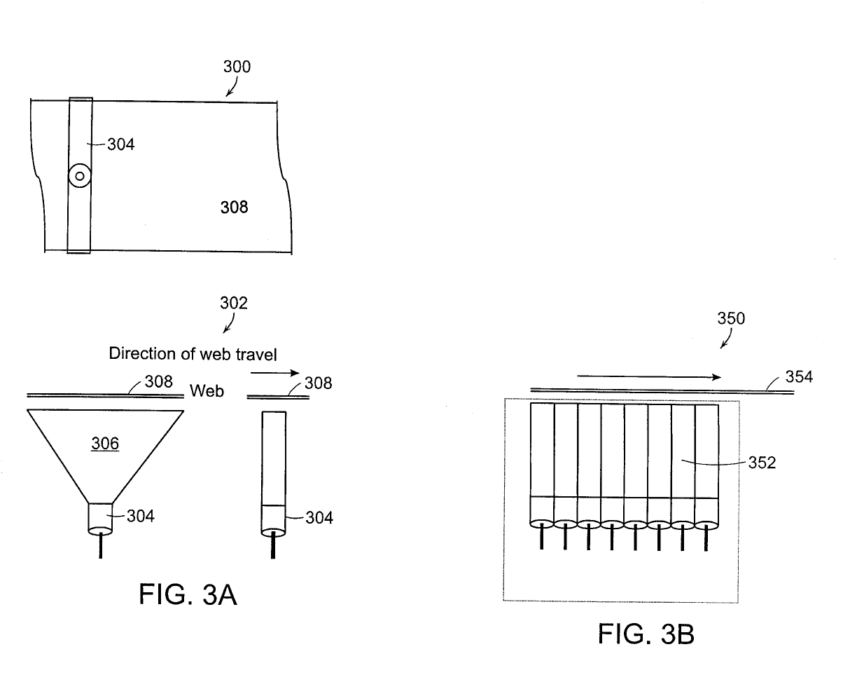

FIGS. 3A-3B illustrate various aspects of vertical process gas injection in a process chamber for a continuous feed CVD system according to the present teaching. FIG. 3A illustrates a bottom-view 300 and a side-view 302 of a single vertical gas source 304 for the continuous feed CVD system according to the present teaching. The bottom-view 300 illustrates a gas injection nozzle 306 that can uniformly distribute process gasses across the entire width of the wafers 308.

FIG. 3B illustrates a side-view 350 of a plurality of vertical gas sources 352 for the continuous feed CVD system according to the present teaching that is positioned along the wafer transport mechanism 354 so that each of the plurality of vertical gas sources 352 distribute process gasses over the surface of the wafer transport mechanism 354. Such vertical gas sources can be easily interchanged to deposit a particular desired material structure on the wafers. Also, such vertical gas sources can be added and/or removed from the system to change the deposition thickness for a particular wafer transport rate.

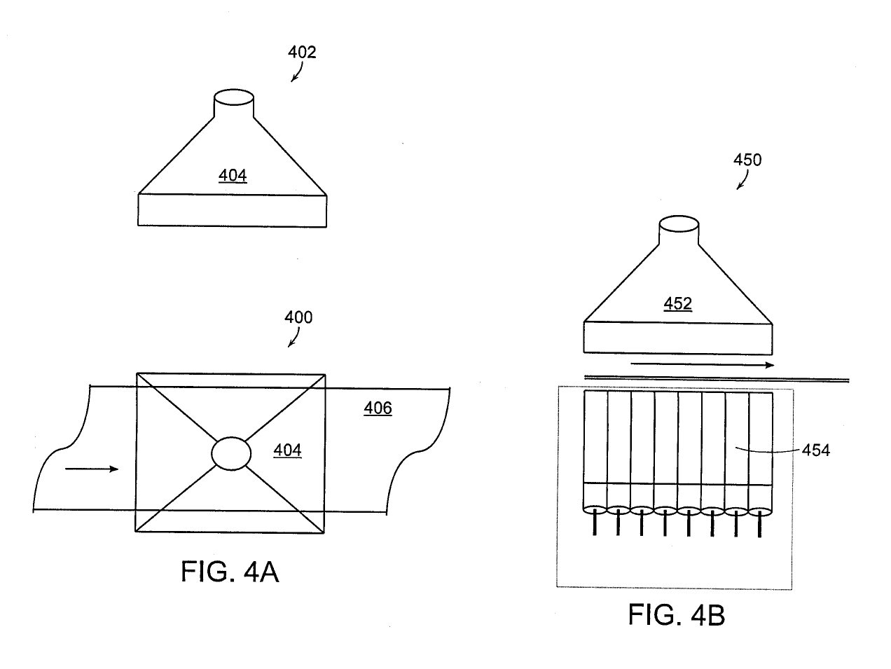

FIGS. 4A and 4B illustrate various aspects of a vertical exhaust port in a process chamber for a continuous feed CVD system according to the present teaching. FIG. 4A illustrates a top-view 400 and a side-view 402 of a single vertical exhaust port 404 for the continuous feed CVD system according to the present teaching. The top-view 400 shows the wafer transport mechanism 406. FIG. 4B illustrates a side-view 450 of a single vertical exhaust port 452 in a process chamber opposite to a plurality of vertical gas sources 454.

Referring to FIG. 1, a method of operating the chemical vapor deposition system 100 according the present teaching includes transporting wafers 104 through a plurality of process chambers 112. The wafers 104 can be heated to a desired process temperature. In some methods, the dimensions of at least one of the plurality of process chambers 112 are changed for a particular CVD process. The wafers 104 can be transported through the plurality of process chambers 112 in only one direction or can be transported through the plurality of process chambers 112 in a forward direction and then in a reverse direction that is directly opposite to the forward direction. In addition, the wafers 104 can be transported through the plurality of process chambers 108 at a constant transport rate or can be transported through the plurality of process chambers 108 in a plurality of discrete steps. In some methods, wafers are transported on air bearing so that films are deposited on the wafers by chemical vapor deposition while the wafers transport through the plurality of process chambers.

The method also includes providing at least one CVD gas to each of the plurality of process chambers at a flow rate that results in the deposition of a desired film by chemical vapor deposition. The at least one CVD gas can be at least one MOCVD gas. The method can include configuring a gas distribution manifold to provide desired CVD gases to at least some of the plurality of process chambers.

In addition, the method includes isolating process chemistries in at least some of the plurality of process chambers 112 by various means. For example, the method can include isolating the process chemistries by generating a gas curtain between adjacent process chambers. Alternatively, the method can include evacuating regions between adjacent process chambers.

### EQUIVALENTS

While the applicant's teaching are described in conjunction with various embodiments, it is not intended that the applicant's teaching be limited to such embodiments. On the contrary, the applicant's teaching encompass various alternatives, modifications, and equivalents, as will be appreciated by those of skill in the art, which may be made therein without departing from the spirit and scope of the teaching.

What is claimed is:

1. A continuous feed CVD system comprising:
a. a wafer transport mechanism that transports wafers during CVD processing;
b. a deposition chamber defining a passage for the wafers to pass through while being transported by the wafer transport mechanism, the deposition chamber comprising a plurality of process chambers that are isolated by barriers which maintain separate process chemistry in each of the plurality of process chambers, each of the plurality of process chambers comprising a gas input port and a gas exhaust port; and
c. at least one CVD gas source that is coupled to the gas input port of each of the plurality of process chambers.

2. The continuous feed CVD system of claim 1 wherein the wafer transport mechanism transport the wafers in only one direction through the plurality of process chambers.

3. The continuous feed CVD system of claim 1 wherein the wafer transport mechanism transports the wafers in a first direction through the plurality of process chambers and then in a second direction, which is opposite to the first direction, back through the plurality of process chambers.

4. The continuous feed CVD system of claim 1 wherein the wafer transport mechanism transport the wafers continuously.

5. The continuous feed CVD system of claim 1 wherein the wafer transport mechanism transport the wafers in a plurality of discrete steps.

6. The continuous feed CVD system of claim 1 wherein the gas input port of at least some of the plurality of process chambers comprises a gas distribution nozzle that substantially prevents CVD gases from reacting until the at least two CVD gases reach the wafers.

7. The continuous feed CVD system of claim 1 wherein at least some of the gas input ports are positioned in an upper surface of the process chamber and corresponding exhaust ports are positioned proximate to at least one side of the process chamber.

8. The continuous feed CVD system of claim 1 wherein at least some of the process chambers are configured with a gas input port proximate to one side of the process chambers and a corresponding exhaust port positioned proximate to another side of the process chambers so that the CVD process gasses flow across the process chambers.

9. The continuous feed CVD system of claim 1 wherein the at least one CVD gas source is injected at opposite sides of alternating process chambers in order to improve deposition thickness uniformity.

10. The continuous feed CVD system of claim 1 wherein at least some of the barriers comprise a gas curtain.

11. The continuous feed CVD system of claim 1 wherein at least some of the barriers comprise a vacuum region between adjacent process chambers.

12. The continuous feed CVD system of claim 1 further comprising a radiant heater positioned proximate to the wafers that heats the wafers to a desired process temperature.

13. The continuous feed CVD system of claim 1 wherein the wafers are positioned in thermal contact with a heating element that heats the wafers to a desired process temperature.

14. The continuous feed CVD system of claim 1 wherein an RF coil is positioned in electromagnetic communication with wafers so as to increase the temperature of the wafers proximate to the RF coil.

15. The continuous feed CVD system of claim 1 wherein the wafer transport mechanism comprises a plurality of air bearing that support the wafers.

16. The continuous feed CVD system of claim 1 further comprising a user configurable gas distribution manifold coupled between the plurality of CVD gas sources and the gas input port of at least some of the plurality of process chambers.

17. A continuous feed CVD system comprising:
a. a means for transporting wafers through a plurality of process chambers;
b. a means for isolating process chemistries in at least some of the plurality of process chambers; and
c. a means for providing a plurality of CVD gases to the plurality of process chambers for depositing a desired film on the wafers in each of the plurality of process chambers by chemical vapor deposition.

18. The continuous feed CVD system of claim 17 wherein the wafer transport mechanism comprises a means for supporting wafers for chemical vapor deposition.

19. The continuous feed CVD system of claim 17 further comprising a means for configuring dimensions of each of the plurality of process chambers for a particular CVD process.

20. The continuous feed CVD system of claim 17 further comprising a gas manifold switching means for configuring a plurality of CVD gas sources so that desired gas mixtures are provided to each of the plurality of process chambers.

21. The continuous feed CVD system of claim 17 further comprising a means for heating the wafer to a desired processing temperature to promote a particular CVD reaction.

22. A method of chemical vapor deposition, the method comprising:
a. transporting a wafer through a plurality of process chambers;
b. isolating process chemistries in at least some of the plurality of process chambers; and
c. providing at least one CVD gas to each of the plurality of process chambers at a flow rate that deposits a desired film on the wafer by chemical vapor deposition.

23. The method of claim 22 wherein the wafer is transported through the plurality of process chambers in a first and a second direction.

24. The method of claim 22 wherein the wafer is continuously transported through the plurality of process chambers.

25. The method of claim 22 wherein the wafer is transported through the plurality of process chambers in a plurality of discrete steps.

26. The method of claim 22 wherein the isolating the process chemistries in at least some of the plurality of process chambers comprises generating a gas curtain between at least some of the plurality of process chambers.

27. The method of claim 22 further comprising heating the wafer to a desired process temperature.

28. The method of claim 22 further comprising configuring a gas distribution manifold to provide desired CVD gases to at least some of the plurality of process chambers.

29. The method of claim 22 further comprising changing dimensions of at least one of the plurality of process chambers for a particular CVD process.
